(19) United States
(12) Patent Application Publication
(10) Pub. No.: US 2025/0323177 A1
(43) Pub. Date: Oct. 16, 2025

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Li-Hsien HUANG, Hsinchu (TW); Tien-Chung YANG, Hsinchu (TW); Hsin-Yu HUANG, Hsinchu (TW); Yao-Chun CHUANG, Hsinchu (TW); Jun HE, Hsinchu (TW)

(73) Assignee: Taiwan Semiconductor Manufacturing Company, Ltd., Hsinchu (TW)

(21) Appl. No.: 18/633,920

(22) Filed: Apr. 12, 2024

(51) Int. Cl. H01L 23/00; H01L 23/31; H01L 25/065

(52) U.S. Cl. CPC H01L 23/562; H01L 23/3185; H01L 24/08; H01L 24/97; H01L 25/0652; H01L 2224/08145; H01L 2224/97

(57) ABSTRACT

A semiconductor package includes a first chip, a second chip, a molding compound and a dielectric layer. The second chip has a lateral surface, a lower surface and a recess recessed with respect to the lower surface. The molding compound is formed on the lateral surface of the second chip. The dielectric layer is formed within the recess.

### BACKGROUND

The semiconductor package includes a chip and a molding compound covering the chip. The molding compound will generate a tearing force resulted from the thermal expansion of the molding compound, and the tearing force often tears the two chips apart. Thus, how to resolve the problem is a goal for those of ordinary skill in the art.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic diagram of a semiconductor package according to an embodiment of the present disclosure;

FIG. 1B illustrates a schematic diagram of a cross-sectional view of the semiconductor package in FIG. 1A; and

FIGS. 2A to 2G illustrate schematic diagrams of manufacturing processes of a semiconductor package in FIG. 1B according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

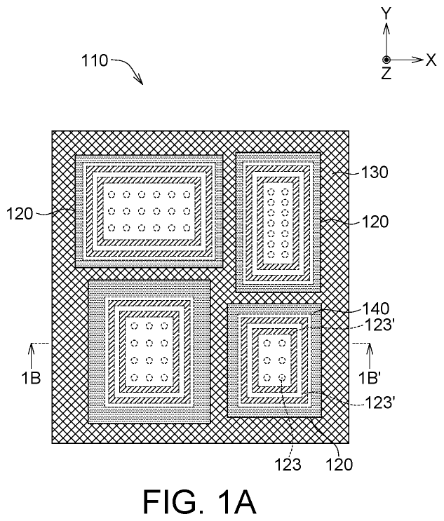

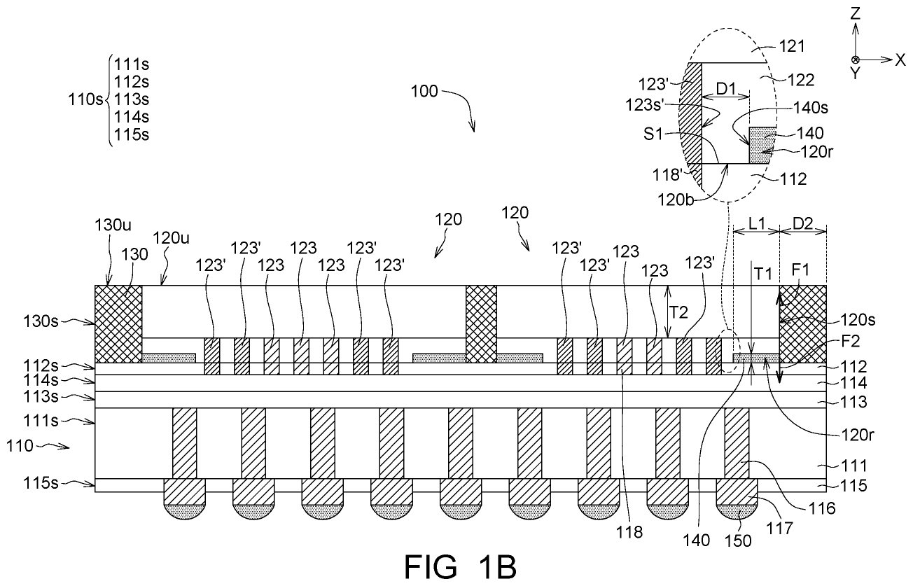

As illustrated in FIGS. 1A and 1B, FIG. 1A illustrates a schematic diagram of a semiconductor package 100 according to an embodiment of the present disclosure, and FIG. 1B illustrates a schematic diagram of a cross-sectional view of the semiconductor package 100 in FIG. 1A.

As illustrated in FIGS. 1A and 1B, the semiconductor package 100 includes a first chip 110, at least one second chip 120, a molding compound 130, a dielectric layer 140 and at least one contact 150. The second chip 120 has a lateral surface 120s, a lower surface 120b and a recess 120r recessed with respect to the lower surface 120b. The molding compound 130 is formed on the lateral surface 120s of the second chip 120. The dielectric layer 140 is formed within the recess 120r. As a result, the dielectric layer 140 may reduce the tearing force resulted from the thermal expansion of the molding compound 130.

As illustrated in FIG. 1B, the first chip 110 includes a first substrate 111, a first bonding layer (or film) 112, a FEOL (Front End of Line) layer 113, a BFEOL (Back End of Line) layer 114, a dielectric layer 115, at least one conductive via 116, at least one conductive pad 117, at least one first conductive contact 118 and at least one seal ring 118′.

As illustrated in FIG. 1B, the first substrate 111 includes, for example, a portion of silicon wafer. The first bonding layer 112 may be formed of a material including. For example, silicon oxide (SiOx), etc. The FEOL layer 113 is formed on a front side of the first substrate 111. The BFEOL layer 114 is formed on the FEOL layer 113. The dielectric layer 115 is formed on a back side of the first substrate 111 and has at least one opening 115a. The conductive via 116 electrically connects the FEOL layer 113 with the conductive pad 117. In an embodiment, the conductive via 116 is, for example, TSV (Through-Silicon Via). The conductive pad 117 is formed on the back side of the first substrate 111 and electrically connected with the conductive via 116 through the opening 115a. The first conductive contact 118 and the seal ring 118′ may be formed of the same material. The first conductive contact 118 and the seal ring 118′ may be formed of a metal including, for example, copper or alloy thereof. As illustrated in FIG. 1A, the seal rings 118′ surround all first conductive contacts 118. The seal ring 118′ is a dummy structure (without circuit function) which may enhance package or chip strength.

As illustrated in FIG. 1B, the second chip 120 includes a second substrate 121, a second bonding layer 122, at least one second conductive contact 123 and at least one seal ring 123′. The second substrate 121 includes, for example, a portion of silicon wafer. The second bonding layer 122 of the second chip 120 has the lower surface 120b and the recess 120r is recessed with respect to the lower surface 120b of the second bonding layer 122, and exposed from the lateral surface 120s. The recess 120r is a shallow trench. The second bonding layer 122 may be formed of a material including. For example, silicon oxide (SiOx), etc. The second conductive contact 123 and the seal ring 123′ may be formed of the same material. The second conductive contact 123 and the seal ring 123′ may be formed of a metal including, for example, copper or alloy thereof. As illustrated in FIG. 1A, the seal rings 123′ surround all second conductive contacts 123. The seal ring 123′ is a dummy structure (without circuit function) which may enhance package or chip strength.

As illustrated in FIG. 1B, the first conductive contact 118 is directly in contact with the second conductive contact 123. In other words, there is a Cu—Cu bond interface between the first conductive contact 118 and the second conductive contact 123. The first conductive contact 118 and the second conductive contact 123 may be bonded by hybrid bonding technology. Similarly, the seal ring 118′ is directly in contact with the seal ring 123′. In other words, there is a Cu—Cu bond interface between the seal ring 118′ and the seal ring 123′. The seal ring 118′ and the seal ring 123′ may be bonded by hybrid bonding technology. In addition, the first bonding layer 112 is directly in contact with the second bonding layer 122. In other words, there is a fusion bond interface between the first bonding layer 112 and the second bonding layer 122. The first bonding layer 112 and the second bonding layer 122 may be bonded by hybrid bonding technology. In an embodiment, the bonding of the first conductive contact 118 and the second conductive contact 123, the bonding of the seal ring 118′ and the seal ring 123′ and the bonding of the first bonding layer 112 and the second bonding layer 122 may be completed in the same hybrid bonding process.

As illustrated in FIG. 1B, when a second thickness T2 of the second substrate 121 of the second chip 120 is greater than 50 μm, in comparison with the oxide, the molding compound 130 is more suitable for filling in a gap between the adjacent two second chips 120.

As illustrated in FIG. 1B, the molding compound 130 has an upper surface 130u, and the second chip 120 has an upper surface 120u, wherein the upper surface 130u and the upper surface 120u are flushed with each other. In addition, the upper surface 130u and the upper surface 120u may be formed in a planarizing process, for example, CMP.

As illustrated in FIG. 1B, the molding compound 130 further has a lateral surface 130s, and the first chip 110 has a lateral surface 110s, wherein the lateral surface 130s and the lateral surface 110s are flushed with each other. Furthermore, the first substrate 111, the first bonding layer 112, the FEOL layer 113, the BFEOL layer 114 and the dielectric layer 115 have a lateral surface 111s, a lateral surface 112s, a lateral surface 113s, a lateral surface 114s, a lateral surface 115s respectively. The lateral surface 110s includes the lateral surface 111s, the lateral surface 112s, the lateral surface 113s, the lateral surface 114s and the lateral surface 115s. In addition, the lateral surface 130s and the lateral surface 110s may be formed in a singulation process.

The molding compound 130 may be formed of a material including, for example, a Novolac-based resin, an epoxy-based resin, a silicone-based resin, or another suitable encapsulant. Suitable fillers also can be included, such as powdered SiO2. The molding compound 130 may be applied using any of a number of molding techniques, such as compression molding, injection molding, or transfer molding.

The molding compound 130 has a CTE (Coefficient of Thermal Expansion) greater than that of the first bonding layer 112 and the second bonding layer 122. The molding compound 130 will generate a first tearing force F1 and a second tearing force F2 to applying to the first bonding layer 112 and the second bonding layer 122.

As illustrated in FIG. 1B, the dielectric layer 140 also may be called “dielectric pre-plug”. Furthermore, in process of forming the second chip 120, the dielectric layer 140 may be pre-formed in the recess 120r.

As illustrated in FIG. 1B, the dielectric layer 140 is formed between the first bonding layer 112 and the second bonding layer 122. The dielectric layer 140 is directly in contact with the first bonding layer 112. The dielectric layer 140 is bonded to the first bonding layer 112 in process of the hybrid bonding.

As illustrated in FIG. 1B, the dielectric layer 140 has a first thickness T1 in a thickness direction Z and a length L1 in a length direction X, wherein a ration (that is, L1/T1) of the length L1 to the first thickness T1 is equal to or greater than 5. The length direction X is perpendicular to the thickness direction Z. In an embodiment, the first thickness T1 may be greater than, for example, 1 micrometers (μm), and/or the length L1 may be equal to or less than 5 μm.

As illustrated in FIG. 1B, the dielectric layer 140 is formed of a material different from that of the first bonding layer 112, the second bonding layer 122 and the molding compound 130. In an embodiment, the dielectric layer 140 may be formed of silicon-based material, for example, SiO2, SIN, SiON, SiCN, etc. In an embodiment, the dielectric layer 140 has a Young's modulus greater than that of the first bonding layer 112 and the second bonding layer 122. As a result, the dielectric layer 140 with high fracture toughness may be produced to avoid crack problem of an interface S1 between the first bonding layer 112 and the second bonding layer 122.

As illustrated in FIG. 1B, the dielectric layer 140 has a terminal surface 140s, and the seal ring 123′ has a lateral surface 123s′ spaced from the terminal surface 140s by a distance D1. The distance D1 is, for example, equal to or greater than 1 μm.

Due to the interface S1 is far away from the molding compound 130 (for example, the length L1 is long enough), the tearing forces F1 and F2 (resulted from the thermal expansion of the molding compound 130) acting on the interface S1 is weakened. Accordingly, the interface S1 between the first bonding layer 112 and the second bonding layer 122 is not damaged. In other words, due to the design of the dielectric layer 140, the first bonding layer 112 keeps contacting with the second bonding layer 122 even if the molding compound 130 occurs the thermal expansion.

The second substrate 121 has the second thickness T2 in the thickness direction Z. The second thickness T2 is, for example, greater than 50 micrometers (μm). For example, the second substrate 121 may range between 50 μm and 775 μm, such as 100 μm, 200 μm, 300 μm, etc. The molding compound 130 has a length D2 in a length direction X. A ratio (that is, L2/D2) of the length D2 to the second thickness T2 is equal to or greater than 5. In an embodiment, the length D2 may be greater than 10 μm.

As illustrated in FIG. 1B, the contact 150 is formed on the conductive pad 117 of the first chip 110. The contact 150 is, for example, solder ball, conductive pillar, conductive bump, etc. The semiconductor package 100 may be disposed and electrically connected with an electronic component through the contact 150, wherein the electronic component is, for example, a PCB (printed circuit board), a semiconductor chip, another semiconductor package, etc.

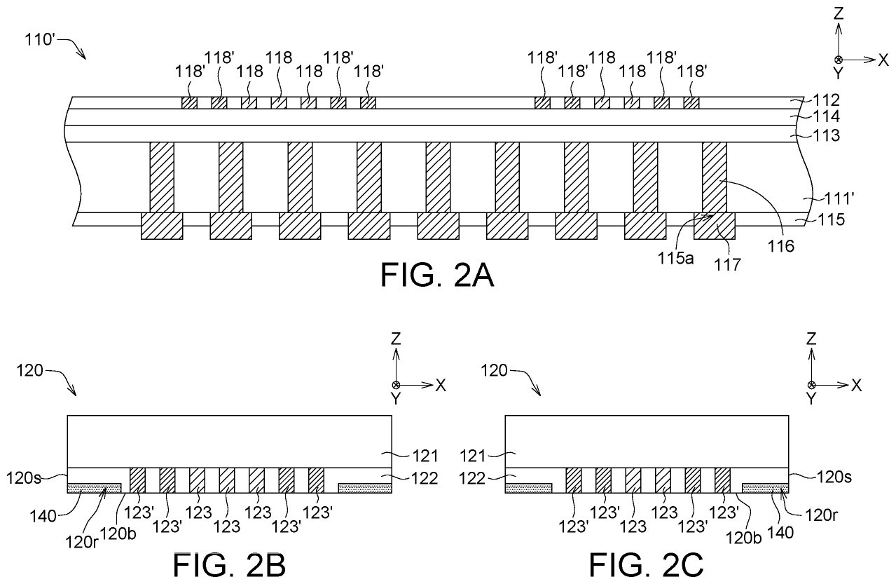

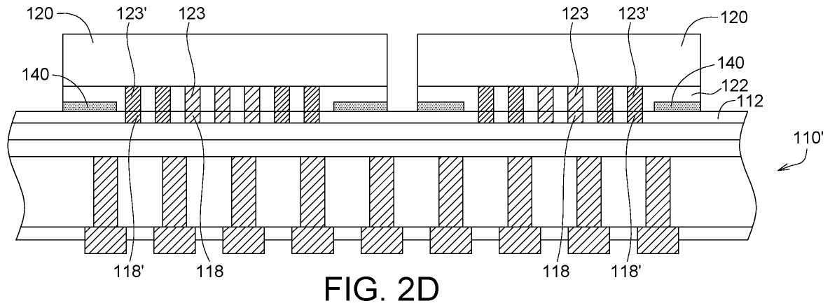

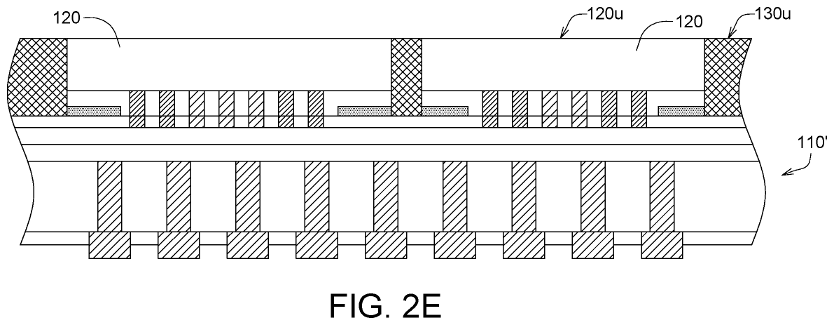

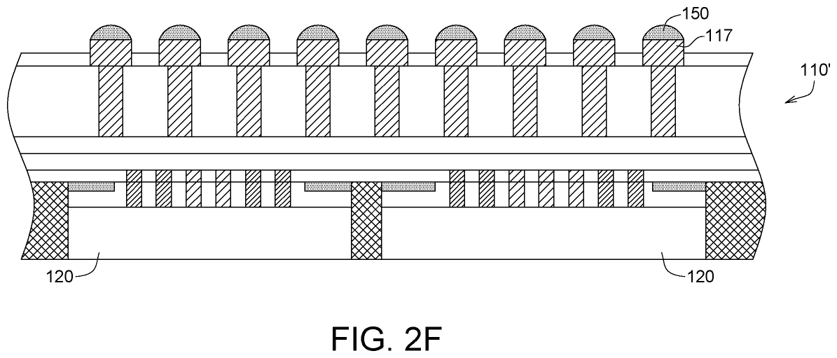

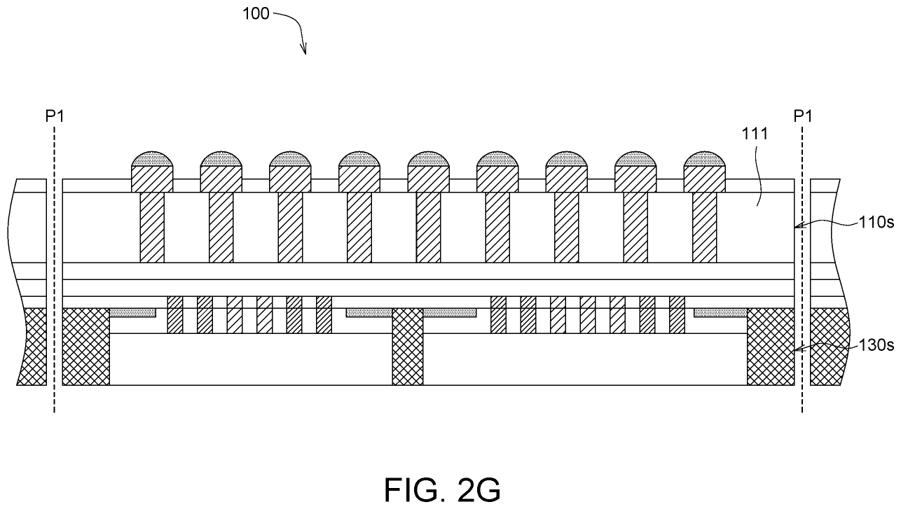

FIGS. 2A to 2G illustrate schematic diagrams of manufacturing processes of a semiconductor package 100 in FIG. 1B according to an embodiment of the present disclosure.

As illustrated in FIG. 2A, the first carrier 110′ is provided. The first carrier 110′ includes a wafer 111′, the first bonding layer 112, the FEOL layer 113, the BFEOL layer 114, the dielectric layer 115, at least one conductive via 116, at least one conductive pad 117, at least one first conductive contact 118 and at least one seal ring 118′. The wafer 111′ is, for example, a un-singulated silicon wafer.

In FIG. 2A, the wafer 111′ is, for example, a un-singulated silicon wafer . . . . The first bonding layer 112 may be formed of a material including. For example, silicon oxide, etc. The FEOL layer 113 is formed on a front side of the wafer 111′. The BFEOL layer 114 is formed on the FEOL layer 113. The dielectric layer 115 is formed on a back side of the wafer 111′ and has at least one opening 115a. The conductive via 116 electrically connects the FEOL layer 113 with the conductive pad 117. In an embodiment, the conductive via 116 is, for example, TSV (Through-Silicon Via). The conductive pad 117 is formed on the back side of the wafer 111′ and electrically connected with the conductive via 116 through the opening 115a. The first conductive contact 118 and the seal ring 118′ may be formed of the same material. The first conductive contact 118 and the seal ring 118′ may be formed of a metal including, for example, copper or alloy thereof. As illustrated in FIG. 2A, the seal rings 118′ surround all first conductive contacts 118. The seal ring 118′ is a dummy structure (without circuit function) which may enhance package or chip strength.

As illustrated in FIGS. 2B and 2C, the second chip 120 in FIG. 2B and the second chip 120 in FIG. 2C are provided. The second chip 120 includes the second substrate 121, the second bonding layer 122, at least one second conductive contact 123 and at least one seal ring 123′. The second substrate 121 includes, for example, a portion of silicon wafer. In other words, the second substrate 121 is singulated silicon wafer.

In FIGS. 2B and 2C, the second substrate 121 includes, for example, a portion of silicon wafer. The second bonding layer 122 of the second chip 120 has the lower surface 120b and the recess 120r is recessed with respect to the lower surface 120b of the second bonding layer 122, and exposed from the lateral surface 120s. The recess 120r is a shallow trench. The recess 120r may be formed by using, for example, photolithography (at least including exposure, development, etching, etc.), etc. The dielectric layer 140 may be pre-formed in the recess 120r by using, for example, deposition, etc. Due to the dielectric layer 140 being pre-formed in the recess 120r (before the forming of the molding compound 130), the dielectric layer 140 may be easy to be controlled to fully fill the recess 120r.

In FIGS. 2B and 2C, the second bonding layer 122 may be formed of a material including. For example, silicon oxide, etc. The second conductive contact 123 and the seal ring 123′ may be formed of the same material. The second conductive contact 123 and the seal ring 123′ may be formed of a metal including, for example, copper or alloy thereof. The seal rings 123′ surround all second conductive contacts 123. The seal ring 123′ is a dummy structure (without circuit function) which may enhance package or chip strength.

As illustrated in FIG. 2D, the second chips 120 are disposed on the first carrier 110′. The first conductive contact 118 and the second conductive contact 123 may be bonded, the seal ring 118′ and the seal ring 123′ may be bonded, and the first bonding layer 112 and the second bonding layer 122 may be bonded by using hybrid bonding technology. After hybrid bonding, the first conductive contact 118 is directly in contact with the second conductive contact 123, the seal ring 118′ is directly in contact with the seal ring 123′, and the first bonding layer 112 is directly in contact with the second bonding layer 122. In other words, there is a Cu—Cu bond interface between the first conductive contact 118 and the second conductive contact 123, there is a Cu—Cu bond interface between the seal ring 118′ and the seal ring 123, and there is a fusion bond interface between the first bonding layer 112 and the second bonding layer 122.

As illustrated in FIG. 2E, the molding compound 130 covering the second chips 120 is formed by, for example, compression molding, injection molding, or transfer molding. Then, the molding compound 130 may be planarized by, for example, CMP (Chemical-Mechanical Polishing). After CMP, the molding compound 130 has the upper surface 130u, and the second chip 120 has the upper surface 120u, wherein the upper surface 130u and the upper surface 120u are flushed with each other.

As illustrated in FIG. 2F, the structure in FIG. 2D may be inverted to make the conductive pad 117 face upward. Then, at least one contact 150 is formed on the corresponding conductive pad 117.

As illustrated in FIG. 2G, at least one singulation passage P1 passing through the molding compound 130 and the first carrier 110′ in FIG. 2F is formed to form at least one semiconductor package 100 by, for example, sawing. After sawing, the first carrier 110′ is singulated to form at least one first chip 110. After sawing, the molding compound 130 further has the lateral surface 130s, and the first chip 110 has the lateral surface 110s, wherein the lateral surface 130s and the lateral surface 110s are flushed with each other.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor package includes a first chip, at least one second chip, a molding compound and a dielectric layer. The dielectric layer is formed between the first chip and the second chip. As a result, the second chip may be packaged more excellently by the molding compound and at the same time the dielectric layer may reduce the tearing force resulted from the thermal expansion of the molding compound.

Example embodiment 1: a semiconductor package includes a first chip, a second chip, a molding compound and a dielectric layer. The second chip has a lateral surface, a lower surface and a recess recessed with respect to the lower surface. The molding compound is formed on the lateral surface of the second chip. The dielectric layer is formed within the recess. The dielectric layer is formed of a material different from that of the molding compound.

Example embodiment 2 based on Example embodiment 1: the first chip includes a first substrate and a first bonding layer on the first substrate, the second chip includes a second substrate and a second bonding layer on the second substrate, and the dielectric layer disposed between the first bonding layer and the second bonding layer.

Example embodiment 3 based on Example embodiment 2: the second substrate has a thickness greater than 50 micrometers.

Example embodiment 4 based on Example embodiment 2: the second substrate has a thickness in a thickness direction, the molding compound has a length in a length direction perpendicular to the thickness direction, and a ratio of the thickness to the length is greater than 5.

Example embodiment 5 based on Example embodiment 2: the dielectric layer has a Young's modulus greater than that of the first bonding layer and the second bonding layer.

Example embodiment 6 based on Example embodiment 2: the second bonding layer of the second chip has the lower surface and the recess recessed with respect to the lower surface of the second bonding layer.

Example embodiment 7 based on Example embodiment 1: the recess is exposed form the lateral surface.

Example embodiment 8 based on Example embodiment 1: the dielectric layer has a thickness and a length, and a ratio of the length to the thickness is greater than 5.

Example embodiment 9 based on Example embodiment 1: the dielectric layer has a terminal surface, the second chip further includes a seal ring spaced from the terminal surface by a distance greater than 1 micrometer.

Example embodiment 10: a semiconductor package includes a first chip, a second chip, a molding compound and a dielectric layer. The second chip has a lateral surface. The molding compound is formed on the lateral surface of the second chip. The dielectric layer is disposed between the first chip and the second chip and is contact with the molding compound.

Example embodiment 11 based on Example embodiment 10: the first chip includes a first substrate and a first bonding layer on the first substrate, the second chip includes a second substrate and a second bonding layer on the second substrate, and the dielectric layer disposed between the first bonding layer and the second bonding layer.

Example embodiment 12 based on Example embodiment 11: the second substrate has a thickness greater than 50 micrometers.

Example embodiment 13 based on Example embodiment 11: the second substrate has a thickness in a thickness direction, the molding compound has a length in a length direction perpendicular to the thickness direction, and a ratio of the thickness to the length is greater than 5.

Example embodiment 14 based on Example embodiment 11: the dielectric layer has a Young's modulus greater than that of the first bonding layer and the second bonding layer.

Example embodiment 15 based on Example embodiment 11: the second bonding layer has a lower surface and a recess recessed with respect to the lower surface and exposed form the lateral surface of the second chip.

Example embodiment 16 based on Example embodiment 10: the dielectric layer has a thickness and a length, and a ratio of the length to the thickness is greater than 5.

Example embodiment 17 based on Example embodiment 11: the dielectric layer has a terminal surface, the second chip further includes a seal ring spaced from the terminal surface by a distance greater than 1 micrometer.

Example embodiment 18: a manufacturing method for a semiconductor package, includes the following steps: providing a first carrier; providing a second chip, wherein the second chip has a lateral surface, a lower surface and a recess recessed with respect to the lower surface; forming the dielectric layer within the recess; forming a molding compound on the lateral surface of the second chip; and forming at least one singulation passage passing through the molding compound and the first carrier, wherein the first carrier is singulated to form a first chip.

Example embodiment 19 based on Example embodiment 18: before forming the molding compound on the lateral surface of the second chip, forming the dielectric layer within the recess.

Example embodiment 20 based on Example embodiment 18: the dielectric layer is formed of a material different from that of the molding compound.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a first chip;
a second chip having a lateral surface, a lower surface and a recess recessed with respect to the lower surface;
a molding compound on the lateral surface of the second chip; and
a dielectric layer within the recess;
wherein the dielectric layer is formed of a material different from that of the molding compound.

2. The semiconductor package as claimed in claim 1, wherein the first chip comprises a first substrate and a first bonding layer on the first substrate, the second chip comprises a second substrate and a second bonding layer on the second substrate, and the dielectric layer disposed between the first bonding layer and the second bonding layer.

3. The semiconductor package as claimed in claim 2, wherein the second substrate has a thickness greater than 50 micrometers.

4. The semiconductor package as claimed in claim 2, wherein the second substrate has a thickness in a thickness direction, the molding compound has a length in a length direction perpendicular to the thickness direction, and a ratio of the thickness to the length is greater than 5.

5. The semiconductor package as claimed in claim 2, wherein the dielectric layer has a Young's modulus greater than that of the first bonding layer and the second bonding layer.

6. The semiconductor package as claimed in claim 2, wherein the second bonding layer of the second chip has the lower surface and the recess recessed with respect to the lower surface of the second bonding layer.

7. The semiconductor package as claimed in claim 1, wherein the recess is exposed form the lateral surface.

8. The semiconductor package as claimed in claim 1, wherein the dielectric layer has a thickness and a length, and a ratio of the length to the thickness is greater than 5.

9. The semiconductor package as claimed in claim 1, wherein the dielectric layer has a terminal surface, the second chip further comprises a seal ring spaced from the terminal surface by a distance greater than 1 micrometer.

10. A semiconductor package, comprising:
a first chip; and
a second chip having a lateral surface;
a molding compound on the lateral surface of the second chip; and
a dielectric layer disposed between the first chip and the second chip and being contact with the molding compound.

11. The semiconductor package as claimed in claim 10, wherein the first chip comprises a first substrate and a first bonding layer on the first substrate, the second chip comprises a second substrate and a second bonding layer on the second substrate, and the dielectric layer disposed between the first bonding layer and the second bonding layer.

12. The semiconductor package as claimed in claim 11, wherein the second substrate has a thickness greater than 50 micrometers.

13. The semiconductor package as claimed in claim 11, wherein the second substrate has a thickness in a thickness direction, the molding compound has a length in a length direction perpendicular to the thickness direction, and a ratio of the thickness to the length is greater than 5.

14. The semiconductor package as claimed in claim 11, wherein the dielectric layer has a Young's modulus greater than that of the first bonding layer and the second bonding layer.

15. The semiconductor package as claimed in claim 11, wherein the second bonding layer has a lower surface and a recess recessed with respect to the lower surface and exposed form the lateral surface of the second chip.

16. The semiconductor package as claimed in claim 10, wherein the dielectric layer has a thickness and a length, and a ratio of the length to the thickness is greater than 5.

17. The semiconductor package as claimed in claim 11, wherein the dielectric layer has a terminal surface, the second chip further comprises a seal ring spaced from the terminal surface by a distance greater than 1 micrometer.

18. A manufacturing method for a semiconductor package, comprising:
providing a first carrier;
providing a second chip, wherein the second chip has a lateral surface, a lower surface and a recess recessed with respect to the lower surface;
forming the dielectric layer within the recess;
forming a molding compound on the lateral surface of the second chip; and
forming at least one singulation passage passing through the molding compound and the first carrier, wherein the first carrier is singulated to form a first chip.

19. The manufacturing method as claimed in claim 18, wherein before forming the molding compound on the lateral surface of the second chip, forming the dielectric layer within the recess.

20. The manufacturing method as claimed in claim 18, wherein the dielectric layer is formed of a material different from that of the molding compound.
